(19) United States
(12) Patent Application Publication
(10) Pub. No.: US 2015/0222247 A1
(43) Pub. Date: Aug. 6, 2015

(54) ANTENNA BRANCHING FILTER

(71) Applicant: Murata Manufacturing Co., Ltd., Nagaokakyo-shi (JP)

(72) Inventor: Kazushi WATANABE, Nagaokakyo-shi (JP)

(21) Appl. No.: 14/688,058

(22) Filed: Apr. 16, 2015

Related U.S. Application Data
(63) Continuation of application No. PCT/JP2013/078051, filed on Oct. 16, 2013.

(30) Foreign Application Priority Data
Oct. 19, 2012 (JP) 2012-232401

(51) Int. Cl. H03H 9/72; H03H 7/38

(52) U.S. Cl. CPC H03H 9/725; H03H 7/38

(57) ABSTRACT

An antenna branching filter includes an antenna terminal, a first filter circuit with a first pass band, and a second filter circuit with a second pass band that does not include the first pass band and with frequencies higher than those of the first pass band. The antenna terminal, the first filter circuit, and the second filter circuit are connected to each other at a first connection point. The second filter circuit includes longitudinally coupled resonator filter circuits. Resonators are provided between the first connection point and the longitudinally coupled resonator filters. Low-frequency band pass circuits with a stop band in the second pass band are provided between second connection points and the ground potential.

### BACKGROUND OF THE INVENTION

1. Field of the Invention

The present invention relates to antenna branching filters, and more specifically relates to antenna branching filters in which intermodulation distortion is significantly reduced or prevented.

2. Description of the Related Art

In mobile communication devices such as cellular phones, an antenna branching filter (duplexer) is widely applied as an electronic component that enables a single antenna to be used for both transmission and reception.

An antenna branching filter 400 of the related art disclosed in Japanese Unexamined Patent Application Publication No. 2005-184143 is illustrated in FIG. 9.

The antenna branching filter 400 includes an antenna terminal 101.

The antenna terminal 101 is connected to a connection point J.

The connection point J is connected to a transmission filter circuit 102. The transmission filter circuit 102 is formed of a ladder (SAW) filter circuit.

In addition, the connection point J is connected to a reception filter circuit 104 via a resonator 103. The reception filter circuit 104 is formed of a longitudinally coupled resonator type SAW filter circuit.

The antenna branching filter 400 having the above-described configuration is characterized in that the resonator 103 is inserted on the antenna side of the longitudinally coupled resonator type filter circuit that forms the reception filter circuit 104.

In the antenna branching circuit 400, the resonator 103 is inserted in series with the antenna terminal 101 and the reception filter circuit 104.

By positioning an anti-resonance point of the resonator 103 in the pass band of the transmission circuit, high impedance characteristics and high attenuation can be obtained in a frequency band that is not wanted in the reception circuit. As a result, degradation of insertion loss inside the pass band of the transmission circuit is suppressed and an effect of obtaining low loss characteristics for the transmission circuit is achieved.

However, with the configuration of the antenna branching filter 400 disclosed in Japanese Unexamined Patent Application Publication No. 2005-184143, there is a problem in that intermodulation distortion (IMD) is generated in the longitudinally coupled resonator type filter circuit and distortion characteristics are degraded.

Intermodulation distortion is generated through the following mechanism.

That is, for example, a signal transmitted from the transmission circuit (ladder filter circuit), more specifically, a signal that has low frequencies compared to the reception frequency band and has a frequency region that causes intermodulation distortion to be generated within or in the vicinity of the reception frequency band due to non-linear characteristics of an element included in the reception circuit (hereafter, generally referred to as low-frequency components) enters the reception circuit. The reception circuit includes the resonator and the longitudinally coupled resonator type SAW filter circuit, but not only signals in the desired reception frequency band but also some of the low-frequency components reach the longitudinally coupled resonator type filter circuit by passing through the resonator.

The low-frequency components that reach the longitudinally coupled resonator type filter circuit interfere with signals in the desired reception frequency band and a distortion signal is generated by intermodulation distortion. In particular, with the configuration of the antenna branching filter 400 disclosed in Japanese Unexamined Patent Application Publication No. 2005-184143, there is a problem in that a distortion signal is easily generated due to intermodulation distortion since a structure is adopted in which low-frequency components become trapped between the resonator and the longitudinally coupled resonator type filter circuit as a result of reflection of signals caused by impedance mismatching.

In particular, when the pass band of the transmission circuit is Tx and the pass band of the reception circuit is Rx, there is a problem in that a distortion signal is generated due to IMD inside the pass band Rx of the reception circuit and in the vicinity of the pass band of the reception circuit when a Tx signal having a frequency band that is lower than the Rx pass band enters the reception circuit.

### SUMMARY OF THE INVENTION

Preferred embodiments of the present invention provide an antenna branching filter in which generation of intermodulation distortion is significantly reduced or prevented.

An antenna branching filter according to a preferred embodiment of the present invention includes an antenna terminal, a first filter circuit with a first pass band, and a second filter circuit with a second pass band that does not include the first pass band and includes frequencies higher than those of the first pass band. The antenna terminal, the first filter circuit and the second filter circuit are connected to each other at a first connection point. The second filter circuit includes a longitudinally coupled resonator type filter circuit. The antenna branching filter further includes a resonator that is provided between the first connection point and the longitudinally coupled resonator type filter circuit, and a low-frequency band pass circuit that is provided between a second connection point, which is a connection point between the resonator and the longitudinally coupled resonator type filter circuit, and a ground potential, and that includes a stop band in the second pass band.

In an antenna branching filter according to a preferred embodiment of the present invention, for example, the longitudinally coupled resonator type filter circuit of the second filter circuit preferably is a balanced longitudinally coupled resonator type filter circuit and includes a first longitudinally coupled resonator type filter and a second longitudinally coupled resonator type filter. The resonator may include a first resonator and a second resonator that have the same or substantially the same frequency characteristics. The low-frequency band pass circuit preferably includes a first low-frequency band pass circuit and a second low-frequency band pass circuit that have the same or substantially the same frequency characteristics. The first connection point, the first resonator and the second resonator preferably are connected to each other at a third connection point. The second connection point may include one second connection point that is a connection point between the first resonator and the first longitudinally coupled resonator type filter, and another second connection point that is a connection point between the second resonator and the second longitudinally coupled resonator type filter. The first low-frequency band pass circuit preferably is provided between the one second connection point and a ground potential and the second low-frequency band pass circuit preferably is provided between the other second connection point and the ground potential. In this case, degradation of the degree of balance between balanced signals caused by variations between the characteristics of the first longitudinally coupled resonator type filter and the characteristics of the second longitudinally coupled resonator type filter are corrected by adjusting the characteristics of the first low-frequency band pass circuit and the characteristics of the second low-frequency band pass circuit.

In addition, in an antenna branching filter according to a preferred embodiment of the present invention, for example, the longitudinally coupled resonator type filter circuit of the second filter circuit preferably is a balanced longitudinally coupled resonator type filter circuit and includes a first longitudinally coupled resonator type filter and a second longitudinally coupled resonator type filter. The resonator, the first longitudinally coupled resonator type filter and the second longitudinally coupled resonator type filter preferably are connected to each other at the second connection point, and a low-frequency band pass circuit preferably is provided between the second connection point and a ground potential. In this case, since the resonator and the low-frequency band pass circuit are each a single component, the degree of balance between balanced signals is corrected by adjusting the characteristics of the common low-frequency band pass circuit without variations between the characteristics of resonators and variations between the characteristics of low-frequency band pass circuits becoming a problem as in the case where a plurality of each of these components is provided.

In addition, in an antenna branching filter according to a preferred embodiment of the present invention, for example, the low-frequency band pass circuit preferably includes an inductance element.

In addition, in an antenna branching filter according to a preferred embodiment of the present invention, for example, the first filter circuit preferably is a transmission filter circuit and the second filter circuit preferably is a reception filter circuit.

As a result of antenna branching filters of various preferred embodiments of the present invention having the above-described configurations, intermodulation distortion in a longitudinally coupled resonator type filter circuit is improved.

That is, the above-described low-frequency components are able to escape to the ground potential via the low-frequency band pass circuit arranged between the connection point between the resonator and the longitudinally coupled resonator type filter circuit, and the ground potential. As a result, the low-frequency components are not trapped between the resonator and the longitudinally coupled resonator type filter circuit and intermodulation distortion in the longitudinally coupled resonator type filter circuit caused by such low-frequency components is significantly reduced or prevented.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is an equivalent circuit diagram of a branching filter 100 according to a first preferred embodiment of the present invention.

FIG. 2 is an equivalent circuit diagram of a branching filter 500 according to a comparative example.

FIGS. 3A and 3B show a graph illustrating pass characteristics of the branching filter 100 according to a preferred embodiment of the present invention illustrated in FIG. 1 and a graph illustrating pass characteristics of the branching filter 500 according to the comparative example illustrated in FIG. 2.

FIG. 4 shows a graph illustrating intermodulation distortion characteristics of the branching filter 100 according to a preferred embodiment of the present invention illustrated in FIG. 1 and intermodulation distortion characteristics of the branching filter 500 according to the comparative example illustrated in FIG. 2.

FIG. 5 is an equivalent circuit diagram of a branching filter 200 according to a second preferred embodiment of the present invention.

FIG. 6 is an equivalent circuit diagram of a branching filter 300 according to a third preferred embodiment of the present invention.

FIGS. 7A and 7B show a graph illustrating pass characteristics of the branching filter 300 according to a preferred embodiment of the present invention illustrated in FIG. 6 and a graph illustrating pass characteristics of the branching filter 500 according to the comparative example illustrated in FIG. 2.

FIG. 8 shows a graph illustrating intermodulation distortion characteristics of the branching filter 300 according to a preferred embodiment of the present invention illustrated in FIG. 6 and intermodulation distortion characteristics of the branching filter 500 according to the comparative example illustrated in FIG. 2.

FIG. 9 is an equivalent circuit diagram of a branching filter 400 disclosed in Japanese Unexamined Patent Application Publication No. 2005-184143.

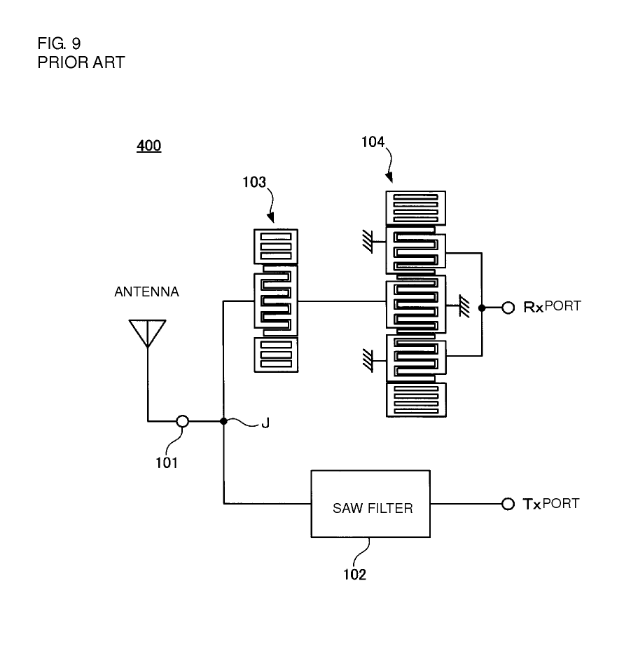

### DETAILED DESCRIPTION OF THE PREFERRED EMBODIMENTS

Hereafter, preferred embodiments of the present invention will be described with reference to the drawings.

### First Preferred Embodiment

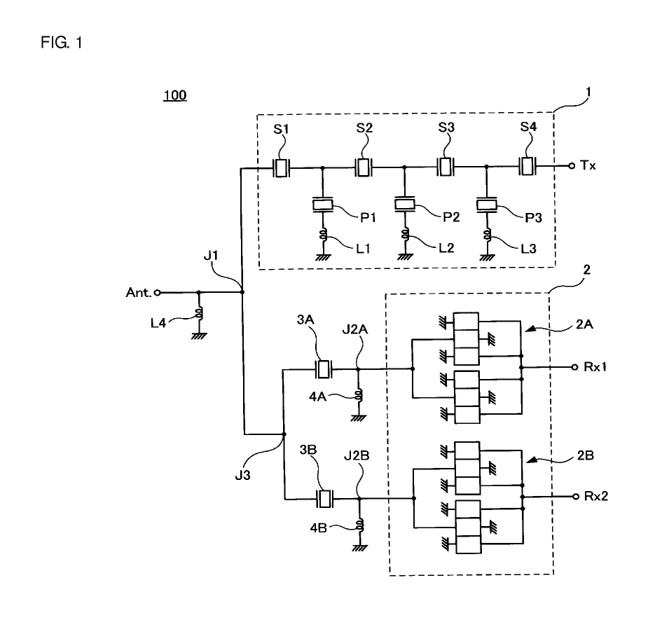

An equivalent circuit diagram of a branching filter 100 according to a first preferred embodiment of the present invention is illustrated in FIG. 1.

The branching filter 100 preferably includes an antenna terminal Ant., a transmission terminal Tx, a first reception terminal Rx1 and a second reception terminal Rx2. In addition, the branching filter 100 preferably includes a first connection point J1, a pair of second connection points J2A and J2B and a third connection point J3.

The branching filter 100 includes a transmission filter circuit 1 that defines and functions as a first filter circuit and has certain pass characteristics. In this preferred embodiment, the transmission filter 1 preferably is a ladder SAW filter circuit and includes series arm resonators S1, S2, S3 and S4, a parallel arm resonator P1 connected to a connection point between the series arm resonators S1 and S2, a parallel arm resonator P2 connected to a connection point between the series arm resonators S2 and S3, a parallel arm resonator P3 connected to a connection point between the series arm resonators S3 and S4, an inductance element L1 provided between the parallel arm resonator P1 and the ground potential, an inductance element L2 provided between the parallel arm resonator P2 and the ground potential and an inductance element L3 provided between the parallel arm resonator P3 and the ground potential.

The branching filter 100 includes a reception filter circuit 2 that defines and functions as a second filter circuit and has certain pass characteristics. In this preferred embodiment, the reception filter circuit 2 preferably is a balanced longitudinally coupled resonator type SAW filter circuit and includes a first longitudinally coupled resonator type filter 2A and a second longitudinally coupled resonator type filter 2B.

In the branching filter 100, resonators are provided on the antenna side of the reception filter circuit 2. The anti-resonant frequency of the resonators is located outside of the low-frequency side of the pass band of the reception circuit and causes greater attenuation of a band that is not wanted in the reception circuit and significantly reduces or prevents degradation of insertion loss in the transmission circuit. In this preferred embodiment, the resonators preferably include a first resonator 3A and a second resonator 3B that have the same or substantially the same frequency characteristics.

The antenna terminal Ant. is connected to the first connection point J1.

The first connection point J1 is connected to one end of the transmission filter circuit 1 defining and functioning as the first filter circuit.

In addition, the first connection point J1 is connected to one end of the reception filter circuit 2, which defines and functions as the second filter circuit, via the resonators. Specifically, the first connection point J1 is connected to the third connection point J3 and the third connection point J3 is connected to one end of the first resonator 3A and one end of the second resonator 3B. The other end of the first resonator 3A is connected to one end of the first longitudinally coupled resonator type filter 2A at one second connection point J2A and the other end of the second resonator 3B is connected to one end of the second longitudinally coupled resonator type filter 2B at the other second connection point J2B.

The branching filter 100 includes a low-frequency band pass circuit having a stop band in the pass band of the reception filter circuit 2, which defines and functions as the second filter circuit according to a preferred embodiment of the present invention. The low-frequency band pass circuit is configured to enable the above-described low-frequency components to escape to the ground potential. In this preferred embodiment, the low-frequency band pass circuit preferably includes a first low-frequency band pass circuit 4A and a second low-frequency band pass circuit 4B. In this preferred embodiment, the first low-frequency band pass circuit 4A and the second low-frequency band pass circuit 4B each preferably include an inductance element. The first low-frequency band pass circuit 4A is provided between the one second connection point J2A and the ground potential. In addition, the second low-frequency band pass circuit 4B is provided between the other second connection point J2B and the ground potential.

In the branching filter 100, an inductance element L4, which is configured to perform impedance matching, is provided between the antenna terminal Ant., the first connection point J1 and the ground potential. In addition, the transmission terminal Tx is connected to the other end of the transmission filter circuit 1, the first reception terminal Rx1 is connected to the other end of the first longitudinally coupled resonator type filter 2A and the second reception terminal Rx2 is connected to the other end of the second longitudinally coupled resonator type filter 2B.

In the branching filter 100 including the above-described equivalent circuit, the above-described low-frequency components are able to escape to the ground potential via the low-frequency band pass circuit (first low-frequency band pass circuit 4A and second low-frequency band pass circuit 4B). As a result, the low-frequency components no longer become trapped between the resonator including the first resonator 3A and the second resonator 3B and the longitudinally coupled resonator type filter circuit including the first longitudinally coupled resonator type filter 2A and the second longitudinally coupled resonator type filter 2B and intermodulation distortion caused by such low-frequency components is reduced. In addition, in the branching filter 100, degradation of the degree of balance between balanced signals that occurs due to variations between the characteristics of the first longitudinally coupled resonator type filter 2A and the second longitudinally coupled resonator type filter 2B is corrected by adjusting the characteristics of the first low-frequency band pass circuit 4A and the characteristics of the second low-frequency band pass circuit 4B.

The branching filter 100 including the above-described equivalent circuit preferably has the following structure, for example.

The branching filter 100 includes a substrate (not illustrated). The substrate preferably is, for example, a ceramic multilayer substrate. The inductance elements L1, L2 and L3 of the transmission filter circuit 1, the first low-frequency band pass circuit (inductance element) 4A, the second low-frequency band pass circuit (inductance element) 4B and necessary wiring lines are provided inside the substrate. Necessary pad electrodes and necessary wiring lines are provided on the surface of the substrate. The antenna terminal Ant., the transmission terminal Tx, the first reception terminal Rx1 and the second reception terminal Rx2 are provided on end portions of the substrate.

The branching filter 100 includes a first SAW device (not illustrated) in which the series arm resonators S1, S2, S3 and S4 and the parallel arm resonators P1, P2 and P3 of the transmission filter circuit 1 and necessary wiring lines are provided on a piezoelectric substrate composed of lithium tantalate or lithium niobate, for example. The first SAW device preferably is flip chip mounted so as to be electrically connected to certain pad electrodes provided on the surface of the substrate.

The branching filter 100 includes a second SAW device (not illustrated) in which the first longitudinally coupled resonator type filter 2A, the second longitudinally coupled resonator type filter 2B, the first resonator 3A, the second resonator 3B and necessary wiring lines are provided on a piezoelectric substrate composed of lithium tantalate or lithium niobate for example. The second SAW device preferably is flip chip mounted so as to be electrically connected to certain pad electrodes provided on the surface of the substrate.

The branching filter 100 includes a chip-type inductance element (not illustrated) that defines the inductance element L4, which is configured to perform impedance matching. The chip-type inductance element is mounted so as to be electrically connected to certain pad electrodes provided on the surface of the substrate.

The branching filter 100 having the above-described structure preferably is manufactured by preparing the substrate, the first SAW device, the second SAW device and the chip-type inductance element, which are manufactured using currently typically used materials and manufacturing methods, and then mounting the first SAW device, the second SAW device, and the chip-type inductance element on the substrate.

In order to confirm the effectiveness of various preferred embodiments of the present invention, the branching filter 100 according to the present preferred embodiment and a branching filter 500 of a comparative example were prepared and the electrical characteristics thereof were compared.

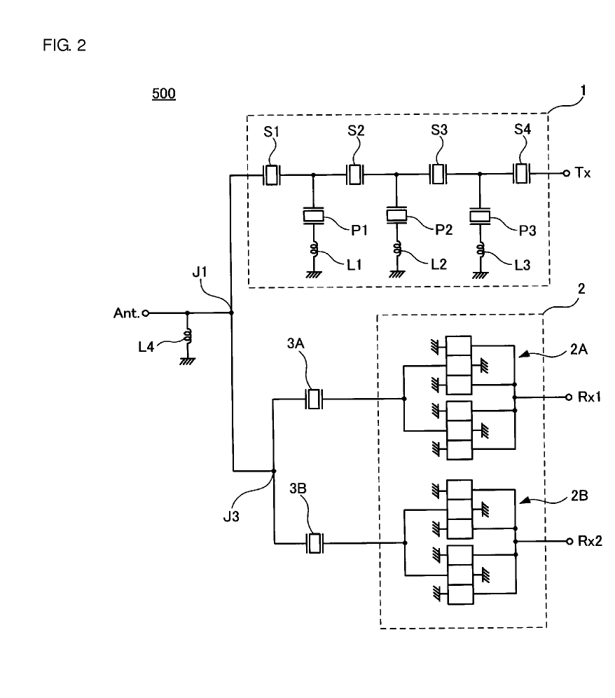

An equivalent circuit diagram of the branching filter 500 according to the comparative example is illustrated in FIG. 2. The branching filter 500 has a structure obtained by omitting the first low-frequency band pass circuit 4A and the second low-frequency band pass circuit 4B from the branching filter 100 of the present preferred embodiment illustrated in FIG. 1. The rest of the configuration of the branching filter 500 is the same as that of the branching filter 100.

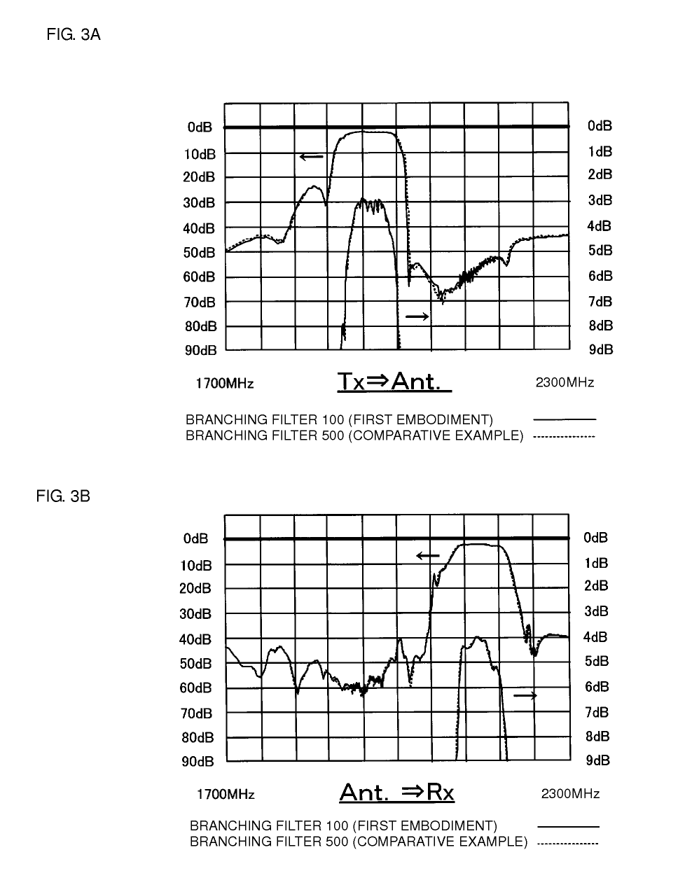

The pass characteristics of the branching filter 100 according to the present preferred embodiment and the pass characteristics of the branching filter 500 according to the comparative example are illustrated in FIGS. 3A and 3B. FIG. 3A illustrates the pass characteristics to the antenna terminal Ant. from the transmission terminal Tx and FIG. 3B illustrates the pass characteristics to the balanced reception terminals Rx (Rx1 and Rx2) from the antenna terminal. In addition, Rx1 and Rx2 respectively represent signals of the balanced reception terminals Rx. As is clear from FIGS. 3A and 3B, the pass characteristics of the branching filter 100 and the pass characteristics of the branching filter 500 are substantially equivalent.

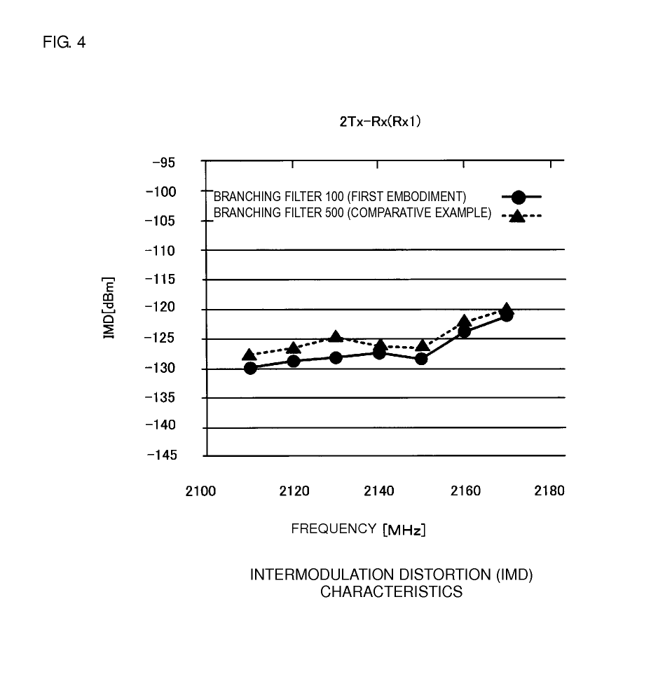

Intermodulation distortion (IMD) characteristics of the branching filter 100 according to this preferred embodiment and intermodulation distortion characteristics of the branching filter 500 according to the comparative example are illustrated in FIG. 4. In FIG. 4, a result is illustrated that IMD is significantly reduced or prevented in the current preferred embodiment in the Rx band, which is a frequency band from about 2100 MHz to about 2180 MHz, for example, in the case where an interference wave in a band of 2Tx-Rx is input. As is clear from FIG. 4, in the measured frequency region from about 2110 MHz to about 2170 MHz, intermodulation distortion is improved in the branching filter 100 compared with the branching filter 500.

Thus, according to various preferred embodiments of the present invention, intermodulation distortion is significantly improved while maintaining the pass characteristics.

In the above-mentioned FIG. 4, it is illustrated that IMD is significantly reduced or prevented in the Rx band, but it is possible to similarly significantly reduce or prevent intermodulation distortion outside of the Rx band such as in bands of 2Tx-Rx, 2Tx+Rx, Tx-Rx and Tx+Rx.

The branching filter 100 according to the first preferred embodiment of the present invention has been described above. However, the present invention is not limited to the above-described contents and may be modified in various ways while not departing from the spirit of the present invention.

In the branching filter 100, the transmission filter circuit 1 preferably is a ladder filter but is not limited to this type of filter and may instead be another type of filter.

In addition, in the branching filter 100, the reception filter circuit 2 preferably is a balanced longitudinally coupled resonator type filter circuit, for example, but instead may be an unbalanced longitudinal coupled resonator type filter circuit.

In addition, in the branching filter 100, the resonator preferably includes the first resonator 3A and the second resonator 3B and the low-frequency band pass circuit preferably includes the first low-frequency band pass circuit 4A and the second low-frequency band pass circuit 4B, but they may instead be each include a single component and respectively include a common resonator and a common low-frequency band pass circuit.

In addition, in the branching filter 100, the inductance element L4 configured to perform impedance matching preferably is specially provided, but the impedance element L4 may be omitted and the low-frequency band pass circuit (first low-frequency band pass circuit 4A and second low-frequency band pass circuit 4B) may instead be given an impedance matching function.

### Second Preferred Embodiment

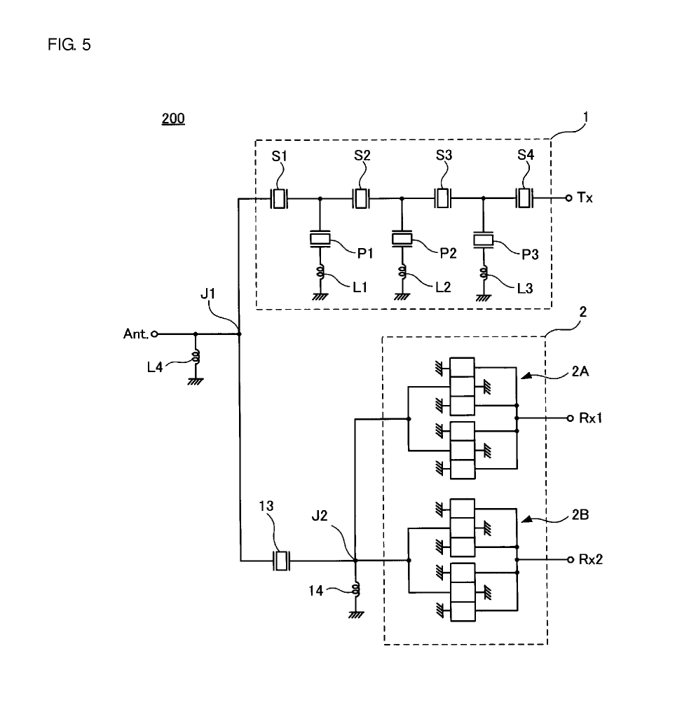

An equivalent circuit diagram of a branching filter 200 according to a second preferred embodiment of the present invention is illustrated in FIG. 5.

In the branching filter 100 according to the first preferred embodiment illustrated in FIG. 1, the resonator preferably includes the first resonator 3A and the second resonator 3B and the low-frequency band pass circuit preferably includes the first low frequency band pass circuit 4A and the second low-frequency band pass circuit 4B, whereas in the branching filter 200 according to the second preferred embodiment they each preferably include a single component, that is, they each respectively preferably include a common resonator 13 and a common low-frequency band pass circuit 14. The common low-frequency band pass circuit 14 is provided between a connection point J2 midway between the common resonator 13 and the reception filter circuit (second filter circuit) 2, and the ground potential. The rest of the configuration of the branching filter 200 is preferably the same as that of the branching filter 100.

Intermodulation distortion is also significantly reduced or prevented in the branching filter 200. In the branching filter 200, since the resonator 13 and the low-frequency band pass circuit 14 each preferably include a single component, the degree of balance between balanced signals is corrected by adjusting the characteristics of the common low-frequency band pass circuit 14 without variations between the characteristics of resonators and variations between the characteristics of low-frequency band pass circuits being a problem as in the case when there are a plurality of each of these components.

### Third Preferred Embodiment

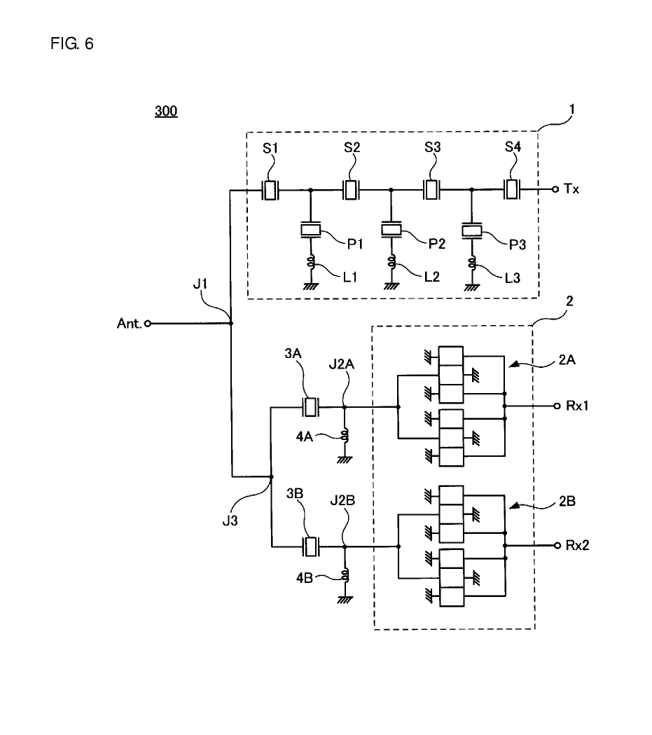

An equivalent circuit diagram of a branching filter 300 according to a third preferred embodiment of the present invention is illustrated in FIG. 6.

In the branching filter 100 according to the first preferred embodiment illustrated in FIG. 1, the inductance element L4 configured to perform impedance matching preferably is specially provided, whereas in the branching filter 300 according to the third preferred embodiment the inductance element L4 is omitted and the low-frequency band pass circuit (first low-frequency band pass circuit 4A and second low-frequency band pass circuit 4B) is given an impedance matching function. The rest of the configuration of the branching filter 300 except for the inductance element L4 preferably is the same as that of the branching filter 100.

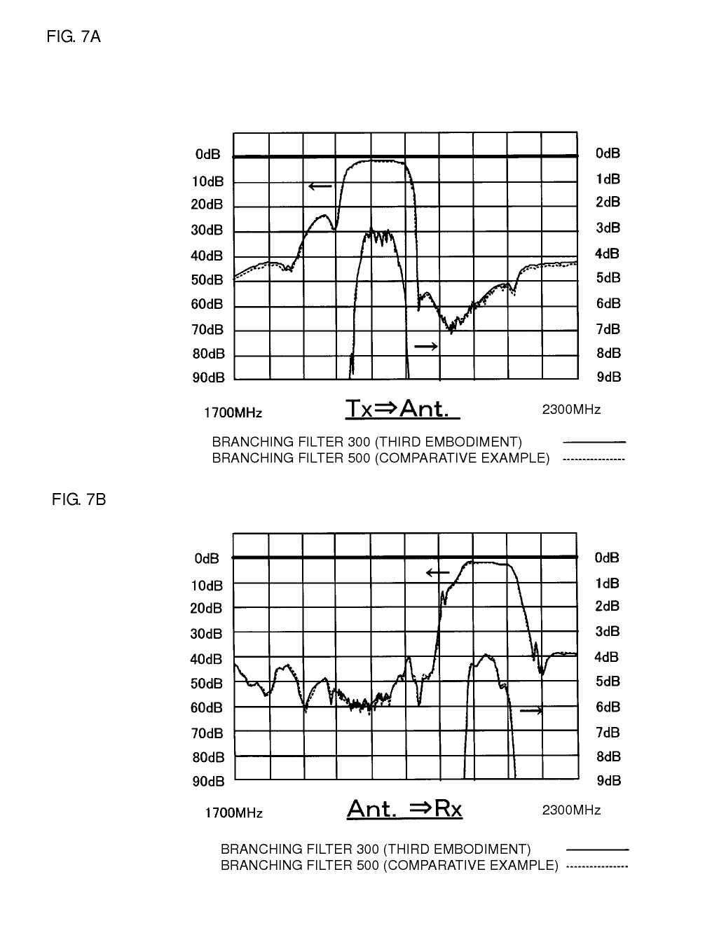

The pass characteristics of the branching filter 300 according to this preferred embodiment and the pass characteristics of the branching filter 500 according to the comparative example illustrated in FIG. 2 are illustrated in FIGS. 7A and 7B. As is clear from FIGS. 7A and 7B, the pass characteristics of the branching filter 300 and the pass characteristics of the branching filter 500 are substantially equivalent.

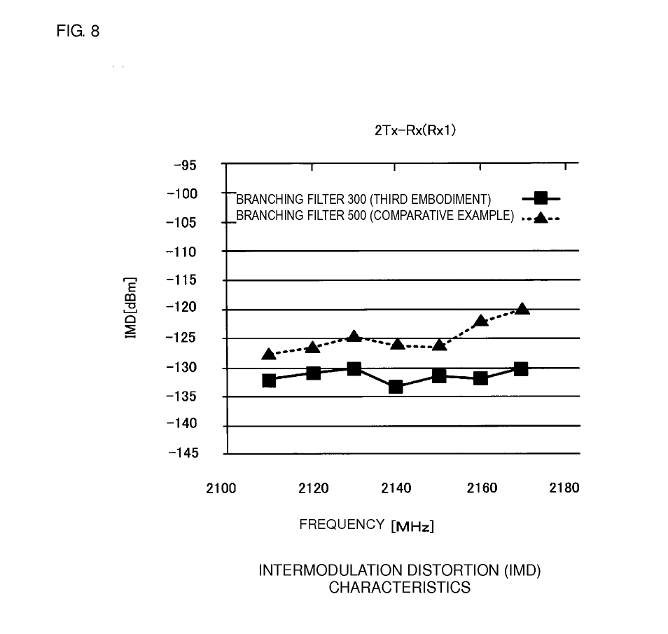

The intermodulation distortion characteristics of the branching filter 300 according to this preferred embodiment and the intermodulation distortion characteristics of the branching filter 500 according to the comparative example are illustrated in FIG. 8. As is clear from FIG. 8, intermodulation distortion is improved in the branching filter 300 compared with the branching filter 500 in the measured frequency region from about 2110 MHz to about 2170 MHz, for example.

As is clear from contrasting FIG. 4 and FIG. 8, the degree of improvement of intermodulation distortion is higher in the branching filter 300 according to the third preferred embodiment illustrated in FIG. 6 than in the branching filter 100 according to the first preferred embodiment illustrated in FIG. 1. The reason for this is as follows.

That is, in the branching filter 300 in which the inductance element L4 is omitted and the first low-frequency band pass circuit 4A and the second low-frequency band pass circuit 4B are configured to perform impedance matching, it is possible to make the inductance values of the first low-frequency band pass circuit 4A and the second low-frequency band pass circuit 4B smaller than in the case where they do not have the impedance matching function and the inductance element L4 is added, and as a result the impedances are also significantly reduced and prevented and the low-frequency components more readily flow to the ground potential.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. (canceled)

2. An antenna branching filter comprising:
an antenna terminal;
a first filter circuit with a first pass band; and
a second filter circuit with a second pass band that does not include the first pass band and with frequencies higher than those of the first pass band; wherein
the antenna terminal, the first filter circuit, and the second filter circuit are connected to each other at a first connection point;
the second filter circuit includes a longitudinally coupled resonator filter circuit;
the antenna branching filter further includes:
a resonator between the first connection point and the longitudinally coupled resonator filter circuit; and
a low-frequency band pass circuit between a second connection point, which is a connection point between the resonator and the longitudinally coupled resonator filter circuit, and a ground potential, and that includes a stop band in the second pass band.

3. The antenna branching filter according to claim 2, wherein
the longitudinally coupled resonator filter circuit of the second filter circuit is a balanced longitudinally coupled resonator filter circuit including a first longitudinally coupled resonator filter and a second longitudinally coupled resonator filter;
the resonator includes a first resonator and a second resonator that have the same or substantially the same frequency characteristics;
the low-frequency band pass circuit includes a first low-frequency band pass circuit and a second low-frequency band pass circuit that have the same or substantially the same frequency characteristics;
the first connection point, the first resonator, and the second resonator are connected to each other at a third connection point;
the second connection point includes one second connection point that is a connection point between the first resonator and the first longitudinally coupled resonator filter, and another second connection point that is a connection point between the second resonator and the second longitudinally coupled resonator filter;
the first low-frequency band pass circuit is provided between the one second connection point and a ground potential; and
the second low-frequency band pass circuit is provided between the other second connection point and the ground potential.

4. The antenna branching filter according to claim 2, wherein
the longitudinally coupled resonator filter circuit of the second filter circuit is a balanced longitudinally coupled resonator filter circuit and includes a first longitudinally coupled resonator filter and a second longitudinally coupled resonator filter;
the resonator, the first longitudinally coupled resonator filter and the second longitudinally coupled resonator filter are connected to each other at the second connection point; and
the low-frequency band pass circuit is provided between the second connection point and a ground potential.

5. The antenna branching filter according to claim 2, wherein the low-frequency band pass circuit includes an inductance element.

6. The antenna branching filter according to claim 2, wherein the first filter circuit is a transmission filter circuit and the second filter circuit is a reception filter circuit.

7. The antenna branching filter according to claim 6, wherein the transmission filter circuit is a ladder SAW filter circuit.

8. The antenna branching filter according to claim 6, wherein the transmission filter circuit includes series arm resonators, parallel arm resonators, and inductance elements.

9. The antenna branching filter according to claim 6, wherein the reception filter circuit is a balanced longitudinally coupled resonator SAW filter circuit.

10. The antenna branching filter according to claim 6, wherein the reception filter circuit includes a first longitudinally coupled resonator filter and a second longitudinally coupled resonator filter.

11. The antenna branching filter according to claim 6, further comprising resonators on an antenna side of the reception filter circuit, wherein an anti-resonant frequency of the resonators is outside of a low-frequency side of a pass band of the reception circuit.

12. The antenna branching filter according to claim 2, further comprising an inductance element configured to perform impedance matching and provided between the antenna terminal, the first connection point and the ground potential.

13. The antenna branching filter according to claim 3, further comprising a multilayer substrate including therein inductance elements of the first filter circuit, the first low-frequency band pass circuit, and the second low-frequency band pass circuit.

14. The antenna branching filter according to claim 3, further comprising a multilayer substrate including end portions included thereon the antenna terminal, a transmission terminal, a first reception terminal and a second reception terminal.

15. The antenna branching filter according to claim 2, further comprising a multilayer substrate and first and second surface acoustic wave devices mounted on the multilayer substrate.

16. The antenna branching filter according to claim 6, wherein the transmission filter circuit is a ladder filter circuit.

17. The antenna branching filter according to claim 6, wherein the reception filter circuit is one of a balanced longitudinally coupled resonator filter circuit and an unbalanced longitudinal coupled resonator filter circuit.

18. The antenna branching filter according to claim 2, wherein the resonator includes first and second resonators and the low-frequency band pass circuit includes the first and second low frequency band pass circuits.

19. The antenna branching filter according to claim 2, wherein the resonator and the low-frequency band pass circuit include a common resonator and a common low-frequency band pass circuit.

20. The antenna branching filter according to claim 2, wherein the antenna branching filter does not contain an inductance element configured to perform impedance matching, and the low-frequency band pass circuit includes a first low-frequency band pass circuit and a second low-frequency band pass circuit configured to perform impedance matching.
